(19) United States
(12) Patent Application Publication
(10) Pub. No.: US 2004/0063008 A1
(43) Pub. Date: Apr. 1, 2004

(54) Post etch overlay metrology to avoid absorbing layers preventing measurements

(75) Inventors: Cyrus E. Tabery, Sunnyvale, CA (US); Christopher F. Lyons, Fremont, CA (US); Srikanteswara Dakshina-Murthy, Austin, TX (US)

Correspondence Address: FOLEY & LARDNER, 777 EAST WISCONSIN AVENUE, SUITE 3800, MILWAUKEE, WI, 53202-5308, US

(73) Assignee: Advanced Micro Devices, Inc.

(21) Appl. No.: 10/255,878

(22) Filed: Sep. 26, 2002

(51) Int. Cl. G03F 7/20; G03F 7/40; G03F 7/36

(52) U.S. Cl. 430/30; 430/313; 430/316; 430/950; 430/317

(57) ABSTRACT

A method of determining overlay layers utilizing advanced lithographic materials utilizes a post-etch overlay metrology. After etching, a relatively opaque layer is removed so that registration markers such as trench isolation structures can be observed. Lithographic parameters associated with the process can be adjusted in accordance with the observations. In a preferred embodiment, an overlay error is determined and adjustments are made to the reduce the overlay error.

### FIELD OF THE INVENTION

The present disclosure relates generally to lithography, especially optical lithography, such as that used for fabricating semiconductor devices, integrated circuits (ICs) and other devices. More particularly, the present disclosure relates to error measurements when using advanced lithographic materials.

### BACKGROUND OF THE INVENTION

Conventional lithographic fabrication systems typically include a semiconductor wafer and one or more layers of materials located on the surface of the wafer. A pattern can be transferred to one or more of the layers of material using a lithographic mask or reticle having a pattern of apertures or object features in the form of an opaque material. Optical radiation is provided to the mask or reticle and is focused by a lens onto a layer of the wafer. In such a fashion, the pattern of the mask is transferred to or printed on the layer of material, typically a photoresist layer.

Generally, lithographic errors such as overlay errors are measured after the photoresist layer is patterned. For example, an overlay error can be related to distances between a gate conductor and neighboring trench regions. Registration marks or structures are observed on the substrate through the relatively translucent photoresist layers and polysilicon layers with optical equipment, such as a scanner or stepper.

The scanner or stepper observes the wafer which is situated on a stage. The scanner or stepper can use the actinic (exposure wavelength), white light, or helium neon (HeNe) light (633 nm) to make overlay measurements. Optical equipment such as a KLA5200 overlay measurement optical microscope manufactured by KLA-Tencor can be utilized to measure lithographic errors associated with a patterned photoresist feature with respect to a marking or structure on the substrate.

According to one conventional process, the STI shallow trench isolation structures or marks can be reasonably observed through the polysilicon layer. After observation of the photoresist feature and the STI marks, an overlay error is determined and the wafer can be reworked if the overlay error is above a threshold. In addition, corrections to alignment and exposure tools can be made in accordance with the overlay error. If the overlay error is below a threshold, the wafer is etched in accordance with the patterned photoresist and the process is continued.

It is desirable to use advanced lithographic materials such as amorphous carbon materials when patterning integrated circuits (ICs). However, overlay measurements cannot be made through the advanced lithographic materials because applicants have observed that amorphous carbon is relatively absorbing at the wavelengths associated with the optical equipment described above. Therefore, conventional processes cannot be employed to measure registration errors when advanced lithographic materials are used.

Thus, there is a need for a method of determining overlay errors when advanced lithographic materials are provided. Further, there is a need to observe registration marks and isolation structures when advanced lithographic materials are utilized. Yet further, there is a need for a process flow which enables the determination of overlay errors when amorphous carbon is utilized in the lithographic process.

### SUMMARY OF THE INVENTION

An exemplary embodiment relates to the system of processing integrated circuits. The method includes lithographically patterning a photoresist layer above a layer including carbon. The layer including carbon is above an underlying layer or substrate including registration features. The method also includes etching the layer including carbon in accordance with the patterned photoresist layer, etching the underlying layer or substrate, removing the layer including carbon, and observing features to determine at least one error factor. The method also includes adjusting lithographic parameters in accordance with the at least one error factor.

Another exemplary embodiment relates to a method of patterning a gate stack above a substrate using a patterned carbon layer. The method includes patterning the gate stack in accordance with the patterned carbon layer, removing the patterned carbon layer, and determining a lithographic error using optical equipment. The optical equipment determines a location of features on the substrate through the gate stack to determine the lithographic error.

Another exemplary embodiment relates to a method of fabricating an integrated circuit above the substrate including trench isolation features. The method includes steps of patterning a photoresist layer above a layer including carbon, etching the layer including carbon in accordance with the patterned photoresist layer, etching the underlying layer, removing the layer including carbon, locating positions of the trench isolation structures to determine an overlay error, and adjusting lithographic parameters in accordance with the overlay error. The layer including carbon is above an underlying layer above the substrate. The underlying layer is translucent. The underlying layer covers at least a portion of the trench isolation structure.

Other principle features and advantages of the invention will become apparent to those skilled in the art upon review of the following drawings, the detailed description, and the appended claims.

### BRIEF DESCRIPTION OF THE DRAWINGS

The exemplary embodiments of the disclosure will hereafter be described with reference to the accompanying drawings, wherein like numerals denote like elements, and:

FIG. 1 is a general schematic block diagram of a lithographic inspection system for scanning a wafer;

FIG. 2 is a more detailed general schematic block diagram of a portion of the wafer;

FIG. 3 is an enlarged schematic block diagram of the portion illustrated in FIG. 2 including a gate structure and four isolation structures;

FIG. 4 is a cross-sectional view of the portion illustrated in FIG. 2 about line 4-4, showing a lithographic patterning step;

FIG. 5 is a cross-sectional view of the portion illustrated in FIG. 4, showing an ARC etching step;

FIG. 6 is a cross-sectional view of the portion illustrated in FIG. 4, showing an amorphous carbon etching step;

FIG. 7 is a cross-sectional view of the portion illustrated in FIG. 6, showing a polysilicon etching step;

FIG. 8 is a cross-sectional view of the portion illustrated in FIG. 7, showing an amorphous carbon layer removal step;

FIG. 9 is a flow diagram showing a process for lithographically patterning an integrated circuit utilizing advanced lithographic materials;

FIG. 10 is a flow chart showing a post-etch overlay metrology in accordance with another exemplary embodiment;

FIG. 11 is a graph showing the translucency of amorphous carbon deposited at 550° C.; and

FIG. 12 is a graph showing the translucency of amorphous carbon including nitrogen deposited at 450° C.

### DETAILED DESCRIPTION OF EXEMPLARY EMBODIMENTS

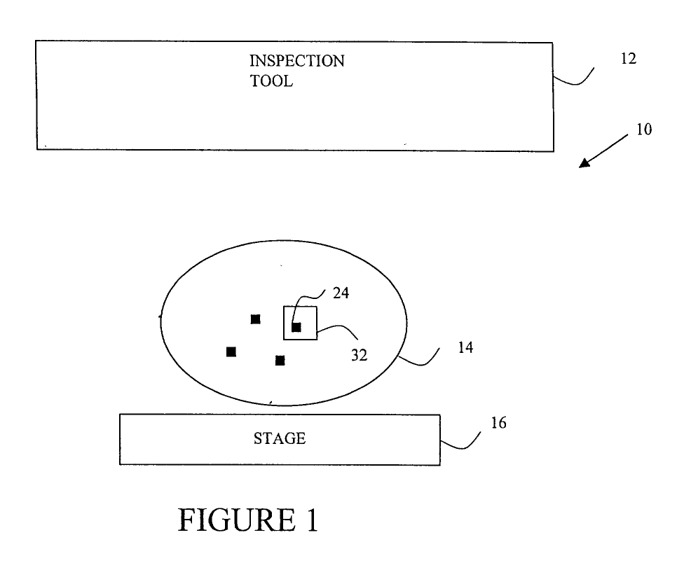

With reference to FIG. 1, an integrated circuit fabrication system is utilized to provide an image to a substrate, such as, a semiconductor or integrated circuit (IC) wafer 14. The image is generally provided as light to wafer 14. The light preferably has a wavelength in the range of 200 nm to 700 nm. The type of semiconductor process, the type of light, the layer being configured on wafer 14, the type of wafer 14, and the type of equipment are not described below in a limiting fashion.

Wafer 14 can be the substrate for a variety of types of integrated circuits including memory units, logic circuits, communications devices, processors, application specific integrated circuits (ASICs), or other devices. Preferably, wafer 14 is a semiconductor (e.g., silicon) wafer upon which insulative, conductive, and semiconductive materials are deposited in an IC fabrication process.

A system 10 is utilized to inspect wafer 14 for lithographic errors, such as overlay errors. System 10 can be implemented in a variety of semiconductor tools and can be included as part of an ultraviolet (UV) light stepper unit. System 10 includes an inspection tool 12 and a stage 16.

With reference to FIG. 1, wafer 14 is provided on a stage 16 and can be viewed (optically analyzed) by inspection tool 12. Inspection tool 12 or system 10 can be a variety of optical inspection tools, including a KLA 5200 manufactured by KLA-Tencor. Wafer 14 includes a portion 32 including integrated circuit structures 24. Integrated circuit structures 24 can be any type of integrated circuit structures which are completed or partially completed.

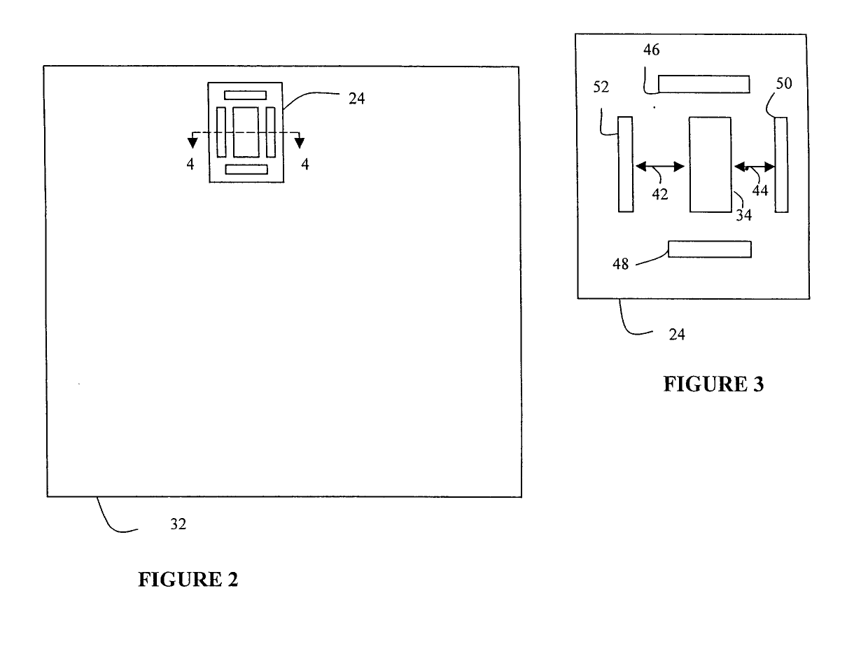

With reference to FIGS. 2 and 3, portion 32 can correspond to an IC chip or device. Portion 32 includes structures 24 which are shown including at least one transistor including a gate conductor 34 surrounded by isolation structures such as shallow trench isolation structures 46, 48, 50 and 52.

Gate conductor 34 is separated from isolation structure 52 by a distance 42 and is separated from an isolation structure 50 by a second distance 44. Ideally, according to preferred design, distances 42 and 44 should be equal. However, due to various semiconductor fabrication accuracy and precision issues, distances 42 and 44 can be different. A particular lithographic error, overlay error, is equal to the difference between distance 44 and distance 42 (e.g., overlay error=D₄₂ minus D₄₄).

Similar errors can be defined by distances between end points of gate conductor 34 and structures 46 and 48, widths of conductor 34 and structures 46, 48, 50 and 52, distances between structures 46, 48, 50, and 52, etc. Further, errors related to other distances can be measured such as, end cap errors, etc. Preferably, system 10 measures these errors as well as other lithographic errors and deviations optically.

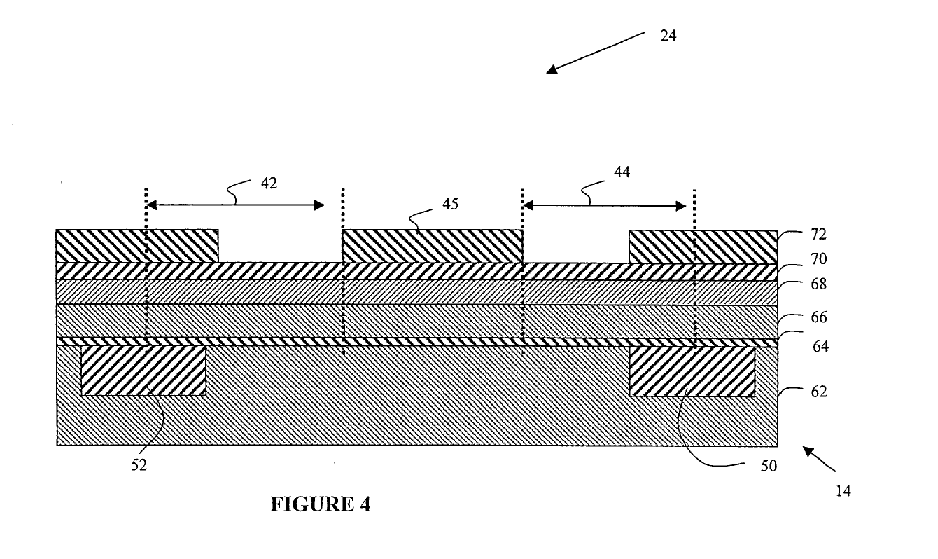

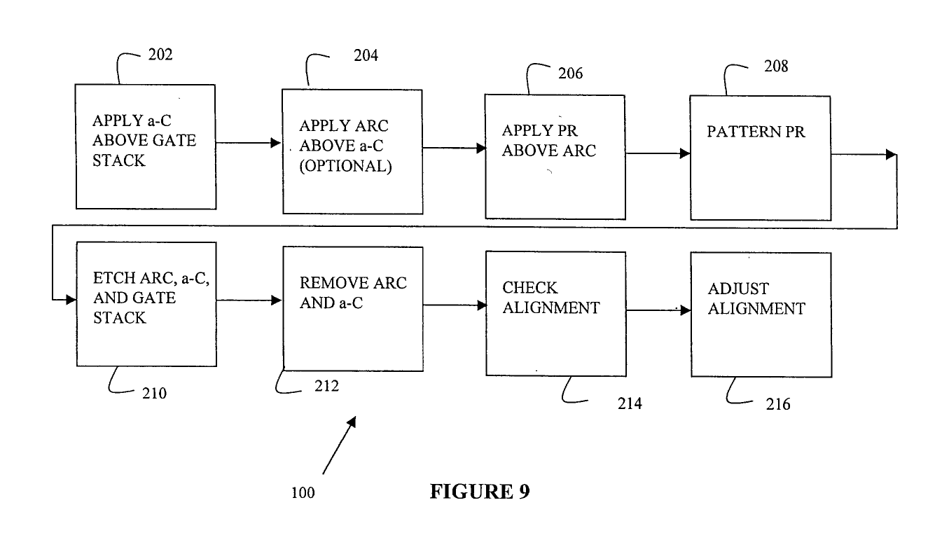

With references to FIGS. 4-9, a process 100 (FIG. 9) for forming portion 32 (FIG. 1) is described below as follows. In FIG. 4, substrate 62 is etched to form trenches which are filled with insulative material such as silicon dioxide to form isolation structures 50 and 52. Structures 50 and 52, as well as structures 46 and 48, can be formed in a conventional shallow trench isolation process.

A thin gate oxide layer or gate dielectric layer 64 is provided above substrate 62. Layer 64 can be thermally grown as a 10-30 Å thick silicon dioxide layer. A gate conductor layer 66, such as a polysilicon layer, is deposited as a 1,000-2,000 angstrom thick layer by chemical vapor deposition (CVD). Layers 66 and 64 comprise a gate stack for the eventual formation of a transistor.

A layer 68 of advanced lithographic material is provided above layer 66. Preferably, layer 68 is a layer containing carbon and can be an amorphous carbon layer. Preferably layer 68 is between approximately 300 and 800 angstroms thick and deposited by plasma-enhanced chemical vapor deposition (PECVD), magnetron sputtering, or a variety of other techniques (e.g., single low-energy beams of carbon ions, dual ion beams of carbon and argon, ion plating, rf sputtering or ion-beam sputtering from carbon/graphite target, vacuum-arc discharges, laser ablation, etc.). Layer 68 can be pure amorphous carbon deposited at approximately 550° C. or can be an amorphous carbon nitrogen layer (e.g., N=0 to 57 atomic percent) deposited at 450° C. Layer 68 is provided in a step 202 of process 100 (FIG. 9).

After layer 68 is provided, an optional antireflective coating (ARC) layer 70 can be provided above layer 68 in a step 204 (FIG. 9). Layer 70 can be a silicon nitride (Si₃N₄), silicon oxynitride (SiON), or other suitable ARC material. Preferably, layer 70 is between approximately 100 and 400 angstroms thick and deposited by PECVD.

After layer 70 is provided, a photoresist layer 72 is provided in a step 206 (FIG. 9). Layer 72 is preferably a positive chemically-amplified type photoresist material and provided by spin coating. In alternative embodiments, other types of photoresist or electron beam resist materials can be used for layer 72. After the provision of layer 72, layer 72 is lithographically patterned to form a feature 45 associated with the eventual formation of gate conductor 34. Any lithographic patterning technique can be utilized to form feature 45.

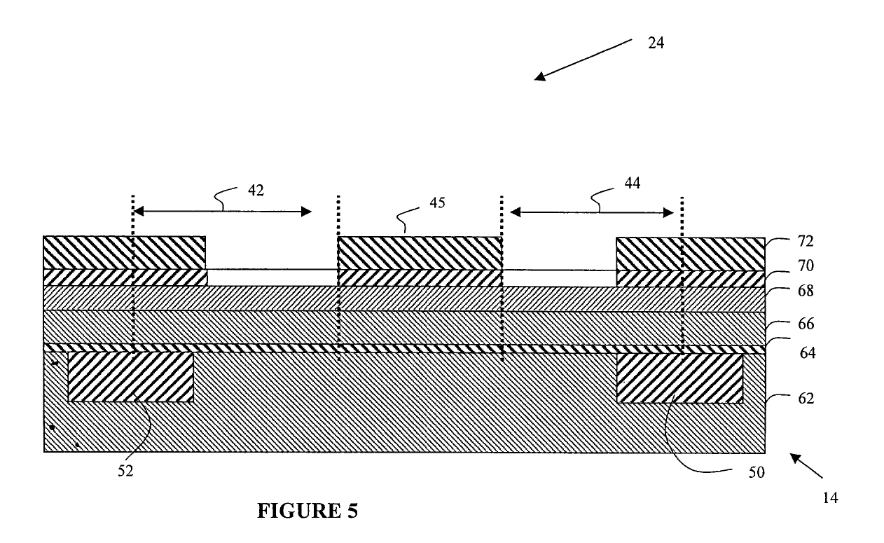

With reference to FIG. 5, layer 70 is etched in accordance with feature 45. Layer 70 can be etched in a dry etching process selective to layer 70 in a step 210 (FIG. 9). At this point in process 100, layer 72 can be optionally removed.

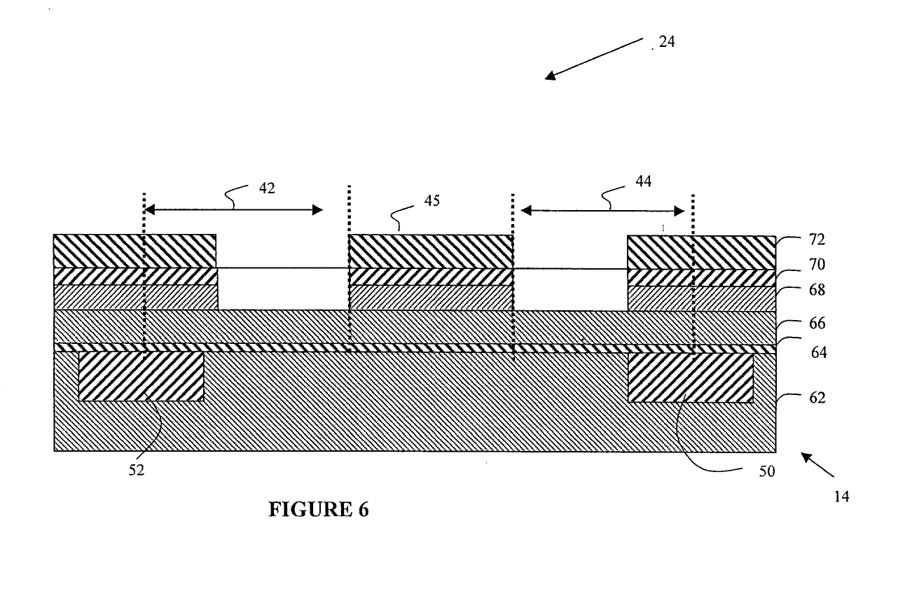

After layer 70 is etched, layer 68 can be etched in a reactive ion etch or plasma etch process in a step 210 (FIG. 6). Preferably, the etch process is selective to layer 68 with respect to layer 66. After step 210, layer 70 can be removed or both layers 70 and 72 can be removed.

Conventionally, after layer 72 is provided, it is desirable to inspect wafer 14 for overlay errors. However, wafer 14 cannot be inspected using conventional optical equipment due to the presence of layer 68 which is relatively opaque.

Applicants have found that when layer 68 is a relatively pure amorphous carbon layer deposited at a temperature of approximately 550° C., layer 68 allows a relatively small percent of transmission through a thickness of 100 nanometers. Applicants have also found that when layer 68 is an amorphous carbon layer including 6 atomic percent nitrogen deposited at approximately 450° C., layer 68 allows a relatively small percent of transmission through a thickness of 100 nm.

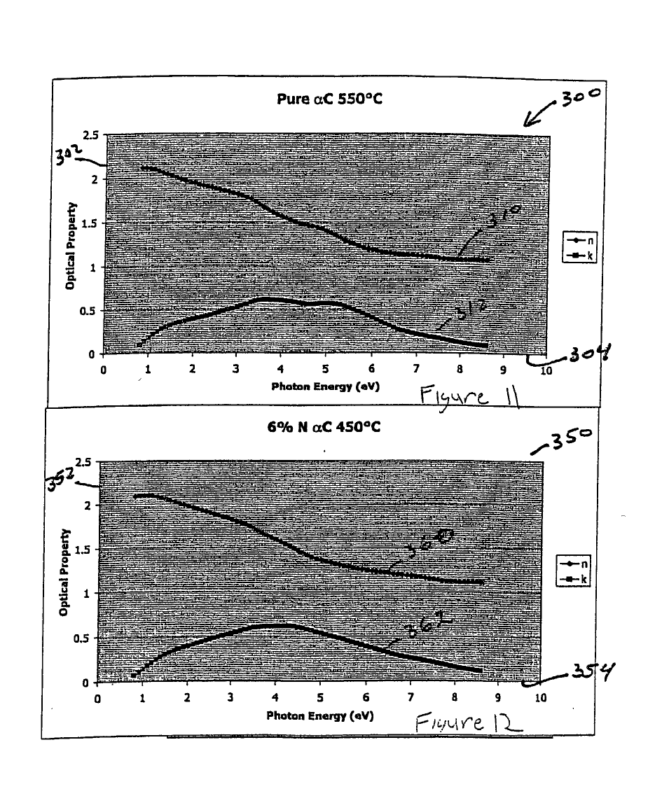

FIGS. 11 and 12 show dispersion spectra 300 and 350 for layer 68 illustrating the optical properties of layer 68. FIG. 11 shows the dispersion spectra 300 for an embodiment where layer 68 is pure amorphous carbon deposited at 550° C. FIG. 12 shows the dispersion spectra 350 for an embodiment where layer 68 is amorphous carbon including approximately 6 atomic percent nitrogen deposited at 450° C. FIGS. 11 and 12 are presented in the form of graphs that plot optical property of layer 68 on the Y-axes 302, 352 and photon energy of incident light in eV on the X-axes 304, 354, where photon energy is determined by the multiplying Planck's constant (6.63×10⁻³⁴ J-s) by the speed of light and dividing by the wavelength of incident light.

Values for the optical constant n (shown as curves 310 and 360 in FIGS. 11 and 12, respectively) and k (shown as curves 312 and 362 in FIGS. 11 and 12, respectively) describe how the material of layer 68 interacts with light. The optical constant n is the ratio of the speed of light in a vacuum to the speed of light as it propagates through the material (e.g., layer 68). The optical constant k is a quantification of the absorption of light in a material. In an exemplary embodiment, optical properties n and k are measured using a Woolam vacuum ultra violet variable angle spectroscopic ellipsometer. Other masurement systems may also be used in alternative embodiments.

As shown in FIGS. 11 and 12, layer 68 absorbs light over the entire spectral range typically used by the overlay measurement tool (e.g., even low energy photons between 3 and 5 eV are strongly absorbed by layer 68, indicated by the large k values). For this reason, overlay measurements are difficult to obtain when layer 68 is present.

The table below includes data showing shows specific data points as plotted in FIG. 11. Optical constants n and k are described above. The variable a quantifies the absorbance of layer 68 per unit length (e.g., micrometers). The variable T represents the transmittance of layer 68, and is calculated according to the formula

T=exp(−a*d)

where T is the transmittance, a is the absorbance per unit length, and d is the thickness of layer 68.

| Photon | Wave- | | | | % T through |
|---|---|---|---|---|---|
| Energy (eV) | length (nm) | N | k | a (1/μm) | 100 nm |
| 7.9 | 156.9 | 1.08 | 0.13 | 10.5 | 35.1 |
| 6.4 | 193.7 | 1.15 | 0.31 | 20.1 | 13.3 |
| 5 | 248.0 | 1.40 | 0.57 | 29.0 | 5.5 |
| 2 | 619.9 | 1.94 | 0.39 | 7.9 | 45.2 |

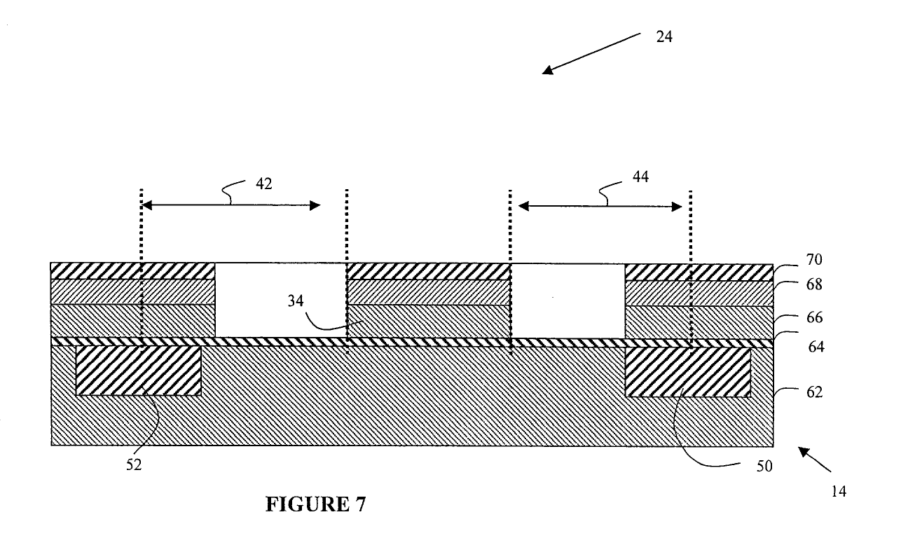

In FIG. 7, in step 210, layer 66 is dry etched in accordance with feature 45 to form gate conductor 34. According to one embodiment, layer 64 can also be etched in a dry etching process at this point. According to another embodiment, layer 64 remains intact. If layer 64 is a translucent layer such as silicon dioxide, it is not required to be removed at this point in process 100.

After layer 66 is etched to form gate conductor 34, layer 68 is removed. In one embodiment, layer 68 and 70 can be removed after etching layer 66 in a step 212. Alternatively, layer 70 can be removed prior to etching layer 66. Preferably, layer 68 is removed by ashing. In one embodiment, an oxygen plasma based removal process is utilized to remove layer 68.

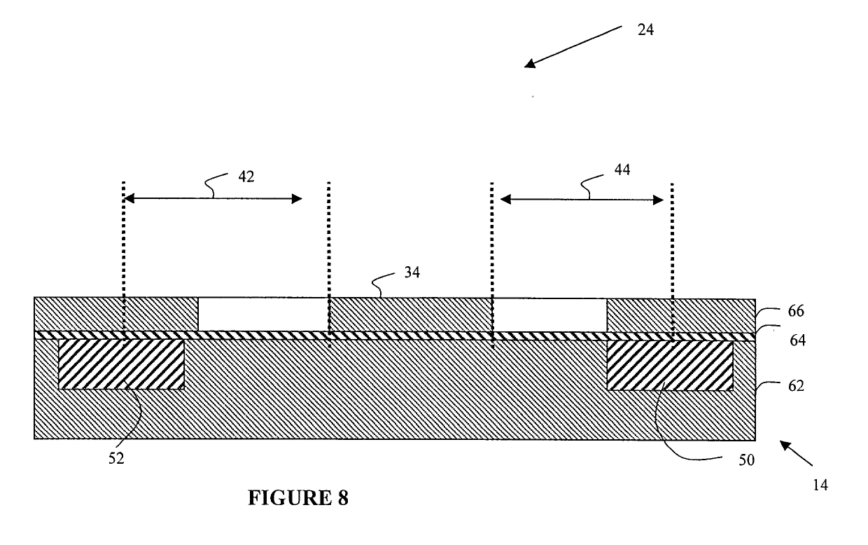

With reference to FIG. 8, a distance 42 and a distance 44 can be used to determine an overlay error for gate conductor 34. Distances 42 and 44 are measured with respect to a center point of isolation structures 52 and 50 with tool 12. After removal of layer 68, alignment can be readily checked in a step 214 because layer 66 is relatively translucent so that alignment marks and/or structures 52 and 50 can be readily observed by system 10. In a step 216, the overlay error can be utilized to adjust fabrication parameters.

Distances 42 and 44 are preferably measured using optical equipment such as a KLA5200 scanner light. A wavelength of between approximately 300 and 600 nanometers can be used to make the measurements. In alternative embodiments, any broad band light wavelengths may be used (e.g., from the mid-visible light spectrum down to the near ultraviolet wavelength ranges).

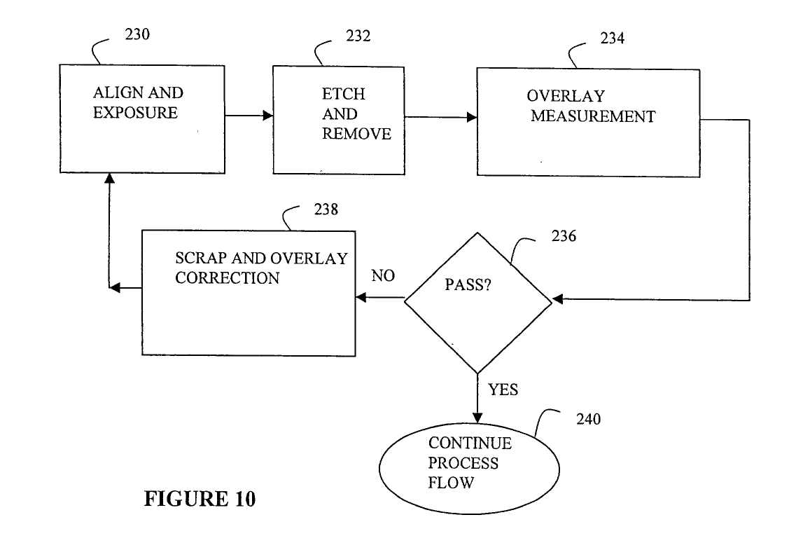

With reference to FIG. 10, a flow chart shows a fabrication process utilizing a principle of a preferred embodiment. At a step 230, wafer 14 is aligned and exposed to pattern photoresist features similar to step 208. At a step 232, wafer 14 is etched through an advanced lithographic material and a gate conductor layer to form a gate stack similar to step 210. Also in step 232, the advanced lithographic layer (e.g., amorphous carbon layer 68) is removed.

At a step 234, an overlay measurement is made. Based upon the overlay measurement made in step 234, a decision to allow wafer 14 to continue processing is made at a step 236. If the overlay measurement is below a threshold, the wafer can be allowed to pass assuming other criteria are met and process flow continues at a step 240. However, if the overlay error is above a threshold or other criteria are not met, the wafer 14 does not pass at step 236 and must be scrapped in a step 238.

Unlike a conventional process which could send wafer 214 for rework, rework is not possible in the preferred embodiment because gate conductor layer 66 has already been etched. However, overlay corrections can still be made and applied to alignment and exposure tools so that subsequent patterning reduces overlay errors.

While the exemplary embodiments illustrated in the FIGURES and described above are presently preferred, it should be understood that these embodiments are offered by way of example only. Other embodiments may include, for example, a variety of other errors. The invention is not limited to a particular embodiment, but extended to various modifications, combinations, and permutations that nevertheless fall within the scope and the spirit of the appended claims.

What is claimed is:

1. A method of processing integrated circuits, the method comprising:
lithographically patterning a photoresist layer above a layer including carbon to form a patterned photoresist layer, the layer including carbon being above an underlying layer or substrate including features;
etching the layer including carbon in accordance with the patterned photoresist layer;
etching the underlying layer or substrate;
removing the layer including carbon;
observing the features to determine at least one error factor; and
adjusting lithographic parameters in accordance with the at least one error factor.

2. The method of claim 1, further comprising:
providing the layer containing carbon, an antireflective coating, and the photoresist layer.

3. The method of claim 1, further comprising:
scrapping the integrated circuit if the at least one error factor is above a threshold.

4. The method of claim 1, further comprising:
continuing process flow for the integrated circuit if the at least one error factor is below a threshold.

5. The method of claim 1, wherein the features are disposed on the substrate and the observing step occurs through the underlying layer.

6. A method of patterning a gate stack above a substrate using a patterned carbon layer, the method comprising:
patterning the gate stack in accordance with the patterned carbon layer;
removing the patterned carbon layer; and
determining a lithographic error using optical equipment, the optical equipment determining a location of features on the substrate to determine the lithographic error.

7. The method of claim 6, wherein the gate stack is translucent at a wavelength of light used by the optical equipment.

8. The method of claim 6, wherein the gate stack includes polysilicon.

9. The method of claim 8, wherein the gate stack includes silicon dioxide.

10. The method of claim 6, wherein the patterned carbon layer is an amorphous carbon layer.

11. The method of claim 10, wherein the amorphous carbon layer includes nitrogen.

12. The method of claim 10, wherein the amorphous carbon layer includes 6% nitrogen.

13. The method of claim 6, wherein the features are shallow trench isolation structures.

14. A method of fabricating an integrated circuit above a substrate including trench isolation structures, the method comprising steps of:
patterning a photoresist layer above a layer including carbon to form a patterned photoresist layer, the layer including carbon being above an underlying layer above the substrate, the underlying layer being translucent;
etching the layer including carbon in accordance with the patterned photoresist layer;
etching the underlying layer, the underlying layer covering at least a portion of the trench isolation structures;
removing the layer including carbon;
locating positions of the trench isolation structures to determine an overlay error; and
adjusting lithographic parameters in accordance with the overlay error.

15. The method of claim 14, wherein the trench isolation structures are shallow trench isolation structures.

16. The method of claim 14, wherein the layer including carbon is an amorphous carbon layer.

17. The method of claim 14, wherein the underlying layer is polysilicon.

18. The method of claim 14, wherein the underlying layer is above a silicon dioxide layer.

19. The method of claim 14, wherein the underlying layer is etched to form gate structures.

20. The method of claim 14, wherein the layer including carbon is removed by a plasma etch using an oxygen plasma at a temperature of less than 400 degrees C.
